(19) United States
(12) Patent Application Publication
(10) Pub. No.: US 2005/0060620 A1
(43) Pub. Date: Mar. 17, 2005

(54) Method of increasing capacity of an optical disc

(76) Inventor: Josh N. Hogan, Los Altos, CA (US)

Correspondence Address: Josh Hogan, 620 Kingswood Way, Los Altos, CA, 94022, US

(21) Appl. No.: 10/938,908

(22) Filed: Sep. 10, 2004

Related U.S. Application Data
(60) Provisional application No. 60/502,075, filed on Sep. 11, 2003.

(51) Int. Cl. G11C 29/00; H03M 13/00

(52) U.S. Cl. 714/718

(57) ABSTRACT

A system that provides increased storage capacity on optical discs includes addressing digital sum variance issues, inter-symbol interference and enhancing detection schemes by means of variable geometry pits to enable higher storage capacity. It further includes enabling copy protection measures to inhibit unauthorized copying of discs.

### CROSS REFERENCES TO RELATED APPLICATIONS

This application, docket number JH040910, claims priority from provisional application, Ser. No. 60/502,075 filed on Sep. 11th, 2003.

### RELATED APPLICATIONS

This invention relates to patent application entitled “A Digital Copy Protection System”, Ser. No. 10/879,609 filed by Josh Hogan on Jun. 29th, 2004, the contents of which are incorporated by reference as if fully set forth herein. This invention also relates to patent application “A Copy Protected Mastering System ”, Ser. No. 10/892,742 filed by Josh Hogan on 16th. Jul. 2004, the contents of which are incorporated by reference as if fully set forth herein.

### FIELD OF INVENTION

The invention relates to recording digital information and in particular to increasing the storage capacity of optical data storage discs.

### BACKGROUND OF THE INVENTION

Digital information, such as, music, software or movies, is typically distributed by recording or embossing the information as digital data on low cost media, such as CD, DVD ROM (read only memory) optical discs. The embossed data is typically physically encoded on the disc as a sequence of pits separated by land regions. The lengths of pits and the land between them are an integral number of a fixed length, referred to as a channel bit.

The data is encoded as a channel bit stream, which is derived from the original digital data by an encoding process. This encoding process includes randomizing the data bytes, adding error correction, address bytes and othe bytes to the original randomized data bytes and transforming the resulting bytes into a run length limited (RLL) bit stream, by means of a modulation code transformation and finally adding predetermined well defined synchronizing bits sequences at periodic recurring intervals.

An RLL code limits the minimum and maximum numbers of “zero” channel bits between successive “ones”. On a physical disc, “ones” correspond to a transition between a pit and land (or land and pit) and “zeros” correspond to a non-changing region of either a pit or land.

When reading back an optical disc, the information is detected by detecting the signals associated with the transitions (or “ones”). The RLL minimum limit is to ensure pits or the land between them are not smaller than the resolution of the optical reading system. The maximum limit is to ensure there are frequently recurring transitions to enable generating an accurate clock from the bit stream.

Modulation codes require more bits to represent the modulated data than the un-modulated data. For example, the modulation code employed in the CD format transforms eight bit data bytes to 14 bit modulation sequences and adds 3 merge bits for a total of 17 bits per 8 bit bytes and is referred to as the EFM modulation code. The DVD format employs an 8 to 16 modulation code, which is referred to as EFMplus. This is a more complex encoding process, however, by requiring only 16 rather than 17 bits to represent an eight bit byte, the storage capacity of the disc is increased by a factor of 1/17, or approximately 6%.

A more efficient 8 to 15 modulation code with has been proposed and is described in U.S. patent application No. 6,002,718 entitled “Method and apparatus for generating run-length-limited coding with DC control”. This modulation code would provide an additional storage capacity increase of approximately 6% and is similar in performance to EFMplus with the exception of its ability to control the low frequency content (or DC characteristics) of the code.

The requirement of being able to control and reduce the low frequency content of a modulation code is critical in ensuring that the bit stream will be correctly read back. This is because the reference level for a bit slicer used to digitize the read back signal is typically derived from the average bit stream signal, which ideally is DC free and has very little low frequency content. The reduced capability of the 8 to 15 code to control the low frequency content makes it unsuitable for a practical system, despite its enabling increased storage capacity.

The typical detection method used for the CD and DVD optical discs was based on peak detection using a bit slicer whose slice reference level is determined by averaging the read-back signal. Peak detection systems typically make a binary decision to digitize the read back signal. Such systems are vulnerable to noise from sources such as interference between adjacent symbols, crosstalk from adjacent tracks and low frequency components within the read back signal.

More advanced detection systems, such as partial response maximum likelihood (PRML) are employed in more advanced optical recording systems, such as Blu-ray or AOD. A typical PRML based detection system digitizes the read back signal with greater dynamic range than binary resolution (typically 4 to 8 bits of resolution ). The digital information is subsequently processed in conjunction with adjacent digitized symbols to produce the binary decision that has the maximum likelihood of being correct. A PRML detection system enables greater insensitivity to interference from adjacent symbols and therefore closer channel spacing, smaller track pitch and therefor increased storage capacity.

The DVD format is frequently used for distribution of movies, where the movie is encoded in a compressed from, typically using a video compression protocol, such as MPEG. Increased storage capacity requires a lower compression factor, which enables a higher quality version of the movie. In particular, as HDTV versions of movies are released, there is a requirement for increased capacity discs.

MPEG encoded movies, typically require a continuous, but varying data rate stream to be available. When reading back data from an optical disc, data could be read continuously but at a fixed data rate. To accommodate the varying data rate requirement, a buffer memory is used and blocks of data are transferred to this buffer memory to ensure data is always available when required. The size of this buffer memory determines the degree of mis-match between data rates that can occur.

Other considerations also affect the size of the required buffer memory. For example, error correction is performed on read back data. This is typically implemented as a two dimensional array, such as a Reed-Solomon Product Code. Typically a small number of errors are corrected on the fly on each line of one dimension of the product code. If there are remaining errors in a line, the whole line is flagged as an erasure, for correction by the second dimension of the code.

Typically, in this second dimension a small number of erasures or errors are corrected on the fly. If there are remaining errors, then the errors are dealt with in an iterative manner. This minimizes the amount of processing hardware required for performing the error correction, however, it introduces a time delay which either requires additional buffer memory capacity or causes an interruption in the data stream.

An interruption in the data stream is typically not an issue when reading back computer data files and indeed fully corrected data (with zero errors) is a ridged requirement. In the case of a video or movie data stream (for entertainment purposes) an interruption in the video sequence is as objectionable as errors, there is therefore no advantage in performing exhaustive iterative error correction unless the buffer memory is increased to accommodate the extra delay.

Another consideration relating to optical data storage is the requirement for copy protection. There is a requirement by content owners to inhibit consumers from readily copying movies from ROM discs to low cost recordable discs. To date there is no successful copy protection mechanism that is not vulnerable to circumvention by easy to use downloadable utility software programs, such as DeCSS.

In light of the considerations described above there is an unmet need for improved video quality of movies by increasing storage capacity, reducing the occurrence of objectionable interruptions and inhibiting unauthorized low cost copying, while enabling low cost by reducing processing requirements and buffer memory size.

### SUMMARY OF THE INVENTION

The invention is a method, apparatus and system for increasing storage capacity of optical discs. The invention includes addressing digital sum variance and inter-symbol interference issues by means of variable geometry pits to enable higher storage capacity. It further includes matching error correction overhead to practical performance and enabling copy protection measures to inhibit unauthorized copying of discs.

### BRIEF DESCRIPTION OF THE DRAWINGS

FIG. 1 is an illustration of a preferred embodiment of the invention.

FIG. 2 is an illustration of a normal land pit sequence with a problematic DSV.

FIG. 3 is another illustration of a normal land pit sequence with a problematic DSV.

FIG. 4 is an illustration of a variable geometry land pit sequence.

FIG. 5 is another illustration of a variable geometry land pit sequence.

FIG. 6 is another illustration of a variable geometry land pit sequence.

FIG. 7 is an illustration of reduced data block suitable for transitional data.

FIG. 8 is an illustration of a set of 33 bit sync sequences.

### DETAILED DESCRIPTION OF THE INVENTION

Consumer digital recording and distribution technologies are constantly being refined to provide higher capacities and faster transfer rates. This is typically accomplished by designing systems that can read and write physical marks, or pits or material property changes with smaller dimensions. For example CD and DVD ROM (read only memory) discs carry recorded information as a continuous spiral land pit sequence. In the case of CDs the minimum pit length is 830 nm and the track pitch is 1600 nm, while on a DVD disc the minimum pit length is 400 nm and the track pitch is 740 nm. This along with other efficiency improvements allows the capacity of the disc to be increased from less than 1 GByte in the CD case to more than 4 GBytes in the DVD case.

For purposes of this application a land pit sequence shall include sequences consisting of depressed regions, typically referred to as pits within a flat or land area and sequences consisting of raised regions, sometimes called bumps, within a flat land area. Also a pit shall refer to any type of information carrying property recorded by a mastering system.

In the case of recordable discs, such as, CD−RW and DVD+RW, the information is recorded by a physical property change, typically a phase change, where information is encoded as a sequence of regions of one phase of the material separated by a region of another phase. These sequences are also referred to as space mark sequences. Once again DVD+RW has a similarly higher capacity than CD−RW due mainly to the ability to write marks with smaller dimensions than DVD. For purposes of this application a mark shall refer to any type of information carrying property recorded by a consumer recording system.

CD or DVD ROM discs are typically manufactured in high volumes by a stamping method that uses a master disc to embosses the land pit sequence onto a plastic (polycarbonate) substrate. The master disc is typically fabricated using a short wavelength laser beam recorder or more recently using electron beam recorders, to define the land pit sequence and an etching process to generate it.

There is constant improvement in the accuracy with which these mastering technologies can be implemented, allowing pits with smaller dimensions and more accurately defined geometries to be generated. This evolution of technology allows later generation ROM discs to be fabricated with variable pit geometries. This provides an opportunity to address recording constraints in a different manner enabling increased capacity discs and can be the basis for a copy protection mechanism.

In particular, the accumulated Digital Sum Variance (DSV), also called Digital Sum Value or Digital Sum Variation, constraint is addressed by flexibility or choices in the modulation code encoding system, however, in typical encoding schemes, symbol sequences exist that allow no opportunity for encoding choice and have problematic DSV characteristics when being recorded or read back.

The ability to record smaller dimensions or variable geometries provides an opportunity to address the accumulated DSV constraint by generating pit sequences with smaller dimensions or variable geometries or a combination thereof. For example, a special long pit could be generated with a narrower width at the center region of the pit, or instead of recording a long pit, a sequence of small pits could be recorded separated by a land region that is smaller than the optical resolution of standard consumer read back devices, or a small dimension pit or sequence of pits could be recorded in what is normally a land region.

The read back signals generated by these special long pits has lower amplitude than an equivalent standard long pit. It therefore contributes less to the DSV than an equivalent standard long pit. The geometry of these special long pits can be specifically designed and selected to act as a DSV control mechanism. Furthermore these special long marks are designed to correctly generate other read back signals, such as front and back pit edge signals and tracking signals.

By removing the requirement for DSV control by means of choice in the modulation code there is greater flexibility in the selection of a modulation code. For example, in the case of the red laser DVD generation, removing the constraint for DSV control allows using a code with a rate of 8 to 15, rather than the standard 8 to 16 rate. This enables increasing the storage capacity of a DVD disc by approximately 6%. Furthermore, other aspects of the storage technology, such as the optical pick up (or head) can remain unchanged, allowing all modification to be performed in the electronic domain. A similar increase in storage capacity of CDs could now be accomplished by using only two merge bits and controlling DSV with variable geometry pits.

In general, the use of variable geometry pits allows discs of higher capacity by use of a more efficient modulation code (i.e. a code requiring fewer bits to represent symbols). The more efficient code may involve encoding a sequence of symbols into a channel bit sequence which may include problematic digital sum variance but can be rendered non-problematic by monitoring the digital sum variance of the channel bit sequence, generating a non-problematic variable geometry land pit sequence and recording the non-problematic variable geometry land pit sequence.

Variable geometry pits can include more elaborate and asymmetric geometries. Accurate and predetermined control of DSV by means of variable geometry enables optical heads to read increased bit density sequences (shorter channel bit lengths). Variable geometry pits can also be used to facilitate and enhance more elaborate detection schemes, such as Partial Response Maximum Likelihood (PRML). This enables a reduction of channel bit dimensions which enables further increase in storage capacity.

Monitoring the adjacent symbols, which can include monitoring symbols along the data track and symbols on neighboring tracks, allows inter-symbol interference of the channel bit sequence to be calculated and compensated for by generating a variable land pit sequence that is designed to pre-compensate for the inter-symbol interference.

Thus, the storage capacity of discs can be increased by monitoring inter-symbol interference of the channel bit sequence, computing a variable geometry land pit that pre-compensates for inter-symbol interference and generating a non-problematic variable geometry land pit sequence with reduced channel bit dimensions. The reduced channel bit dimensions refer to the distance along a track that defines a bit of information or the track pitch. A typical land or pit has a length corresponding to an integer number of channel bits. Conventional lands and pits are replaced with sequences that can include multiple variable geometry pits that constitute a non-problematic variable geometry land pit sequence.

The variable geometry land pit sequence is non-problematic in that the variable pit geometry reduces digital sum variance and pre-compensates for inter-symbol interference. The non-problematic aspect may also include pre-compensation for characteristics of the read channel and detection schemes, such as PRML read channel detection schemes. Including variable pit geometries that are designed to also enhance PRML detection of sequences with reduced channel bit dimensions enables further increase of storage capacity.

Storage capacity can be further increased in situations which require a continuous data stream by optimizing the error correction overhead. In the case of video data, such as movies, or audio data such as music, being stored on the disc there is little practical value in extensive error correction codes (ECC) that require time consuming iterative processing. This is because the interruption caused by the processing delay is at least as objectionable as uncorrected errors. Furthermore, there are opportunities to conceal errors with techniques such as, those based on replication and motion prediction.

Not storing the unusable error correction bytes provides an opportunity for additional data storage. For example, in the case of DVD reducing the second level error correction from 16 to 8 lines, when combined with the increased capacity of the higher rate modulation code enables increasing the capacity by approximately 10%. Furthermore, the smaller physical size of these reduced 32 Kbyte error correction user data blocks, allows interleaving of two blocks, without them overlapping at the inner diameter of the user data area. This allows the same protection against burst errors as the non-reduced error correction blocks.

In order to correctly decode these reduced ECC blocks with 8 to 15 they must be appropriately tagged to distinguish them from normal data blocks. This can be done by always having normal blocks in the area that precedes the user data area and identifying and tagging the reduced blocks there. For example, this information could be added to the table of contents or file address list. This allows all standard drives to read the file system related area of the disc and then drives not enabled to read the 8 to 15 code can ignore that portion of the disc in an orderly manner, while enabled drives could correctly read the reduced blocks.

In the standard red laser DVD generation format, the basic bit stream structure consists of a unit of 1488 channel bits (herein referred to as a sync frame), which is comprised of 91 sixteen bit codes corresponding to 91 eight bit data bytes plus a thirty two bit synchronization code (Sync). A portion of the Sync code is identical in all Sync codes to enable synchronization to the data structure. Twenty six frames constitute a data sector and sixteen data sectors constitute an ECC block.

The same 1488 bit structure can be retained but now be comprised of 97 fifteen bit codes corresponding to 97 eight bit data bytes plus a thirty three bit synchronization code (Sync). A portion of the thirty three bit Sync code can again be used for synchronization. The remaining bits can accomplish correct decoding of the last byte, DSV control, some address information and also an additional very low data rate sub-channel. This low data rate sub channel could carry as much as one data bit per Sync.

Furthermore, utilizing variable geometry pits to address DSV issues, releases the Sync sequences of the existing red laser DVD format from the DSV control requirement, enabling the choice of Sync sequences to be used to carry sub-channel data. In general, utilizing variable geometry pits to address DSV issues, releases the Sync sequences of any format from the DSV control requirement, enabling the choice of Sync sequences to be used to carry sub-channel data.

Unlike other proposed sub-channels, this approach is implemented at rigidly pre-determined locations and therefore has a guaranteed data rate, which enables realistic implementations (not based on statistical probabilities). Furthermore, copy protection measures based on other proposed sub-channels are vulnerable to “long reads” and “long writes” where all the symbols in an error correction block can be read and written to (for legitimate test purposes) and thus provide a mechanism for discovering or tampering with the sub-channel data.

The sub-channel of this invention exists at a level below the modulation code level and can be made available only to stamped discs and not recordable by consumer writers or made available to consumer writers but with reduced or different capabilities. For example, in consumer writers access to the syncs associated with a restricted set of data sectors (or sync frames or ECC data blocks. For purposes of this application a data sector includes any combination of sync frames) would be enabled for selecting synchronizing bit sequences.. This enables a secure sub-channel for stamped discs that cannot be duplicated by a consumer writers and also a reduced version being available to consumer writers that does not compromise the copy protected status of stamped discs.

The sub-channel is suitable for carrying a sequence of bits that is copy protection related data, including, but not limited to, encryption, decryption or descrambling related data. It is also suitable for carrying encryption, decryption or descrambling related keys, such as public or private keys. For the purpose of this application, decryption related data shall refer to encryption, decryption or descrambling keys and associated data. This can form the basis for a copy protection scheme that includes a watermark or watermarks containing related cryptographic data. Rather than a watermark other hidden, (steganographic) or encrypted information could be cryptographically related to the sub-channel data. For purposes of this application watermark includes steganographic and encrypted data and decryption related data.

The copy protection scheme, is based on the watermark being difficult to remove and would point to the presence of complimentary data in the Sync sub-channel. The sub-channel data is volatile in that it is not contained in user data and therefore will not be contained in an unauthorized copy of even a byte for byte copy.

Because the sub-channel is not covered by normal ECC, the sub-channel could also contain error correction data to ensure the recovered sub-channel data can be correctly decoded. Steganographic data is typically difficult to identify and encrypted information is typically required to use the data on the disc and therefore difficult to remove and therefore require the presence of the sub-channel decryption related data.

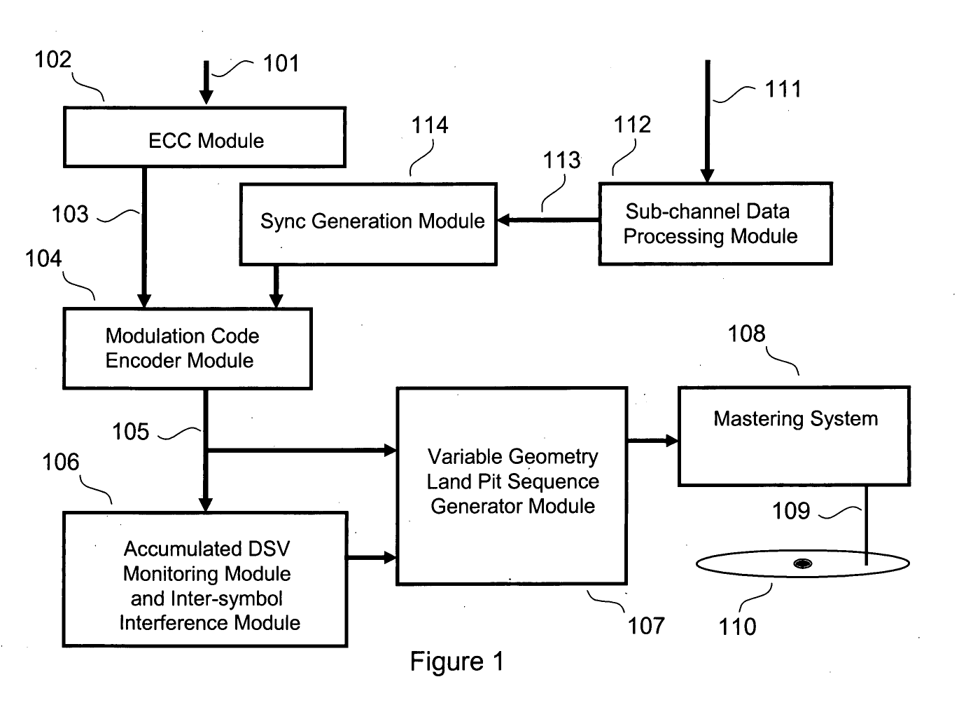

A preferred embodiment of this increased storage capacity system is illustrated in and described with reference to FIG. 1, where a tagged data stream 101 is applied to an ECC module 102. Data blocks that are required to be read in a continuous manner without interruption are appended with a reduced number error correction symbols, thus increasing the storage capacity of the disc. Normal data blocks are appended with a complete number of error correction symbols. The resulting sequence of symbols forms the output 103 of the ECC module.

The output 103 of the ECC module 102 is applied to a modulation code encoder module 104 that encodes the sequence of symbols into a channel bit sequence. The channel bit sequence 105 is applied to the accumulated DSV monitoring and inter-symbol interference module 106 where the DSV is monitored and the relationship between adjacent channel bit symbols is analyzed to produce variable pit geometry information that reduces DSV and pre-compensates for inter-symbol interference. This may also include pre-compensation for detection schemes, such as, a PRML detection scheme.

The variable geometry pit information is provided to the variable geometry land pit sequence generator module 107. This module 107 also receives the channel bit sequence 105 and generates the control signals necessary for the mastering system 108 to generate a modulated laser beam (or beams) 109 to record a the variable geometry land pit sequence on the disc 110.

Decryption related data 111 is also applied to a sub-channel data processing module 112 where the decryption related data has error correction bits added and forms a first sequence of bits 113. The first sequence of bits 113 is applied to a sync generation module 114 that selects synchronizing bit sequences based on the first sequence of bits. This information is applied to the modulation code encoder module 104 where the selected synchronizing bit sequences are combined with a second sequence of bits. The second sequence of bits is the channel bit sequence prior to insertion of the synchronization bit sequences and typically includes, but is not limited to, the modulation code bits of the user data with associated address and associated error correction data.

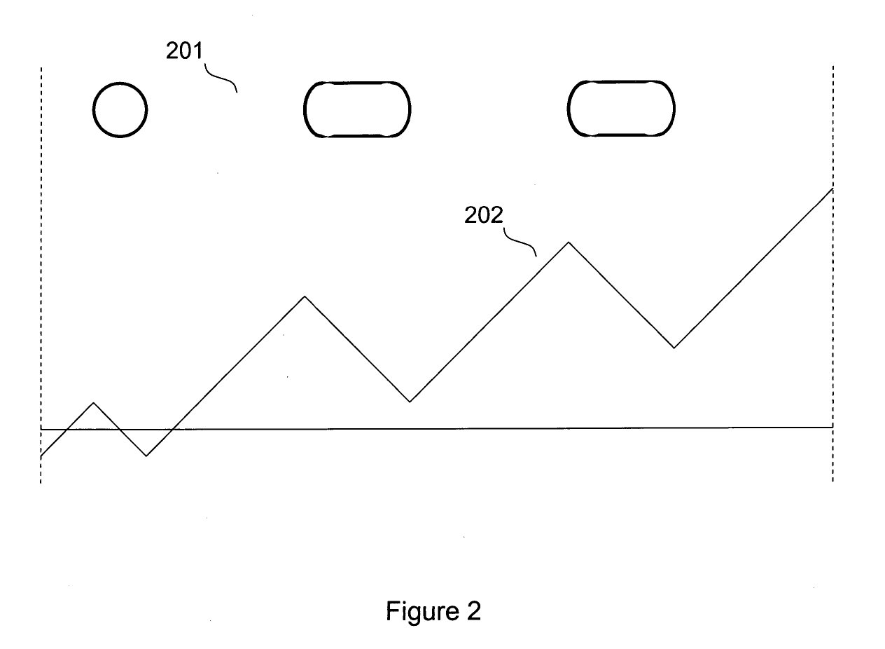

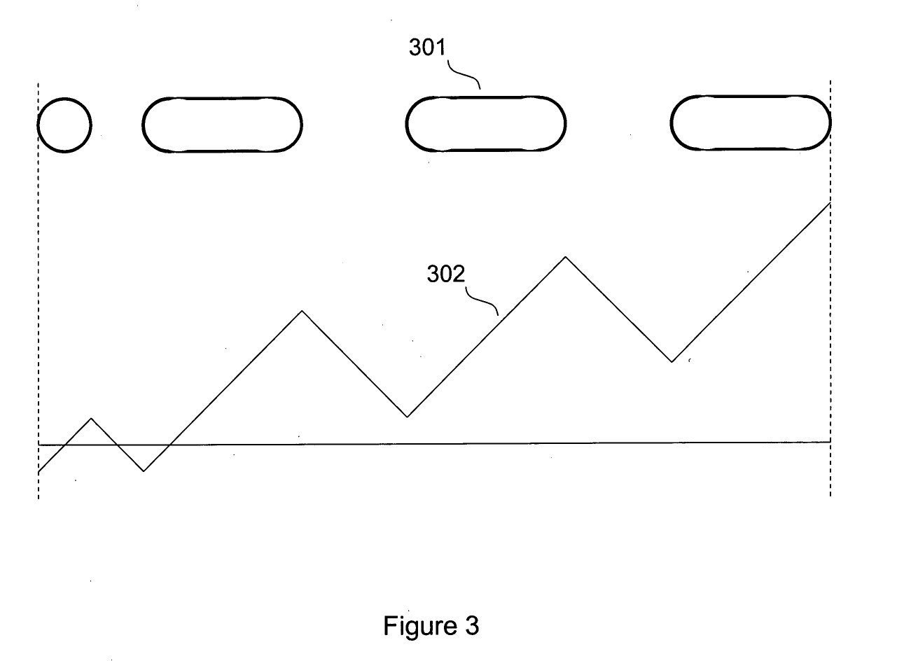

FIG. 2 illustrates the DSV signal 202 of a normal land pit sequence, having land regions 201 containing normal pits and no variable geometry pits in land areas. Note, for purposes of this application the polarity of the signal is not significant, as is indicated in FIG. 3 which is similar to FIG. 2 with land and pits swapped with indicating a normal pit 301 and the DSV signal 302. (Note: the illustrated DSV signals 202 and 302 are simplified. In fact the real signal would be more complex, the illustrated signal represents an averaged slope characteristic of the average reflected signal).

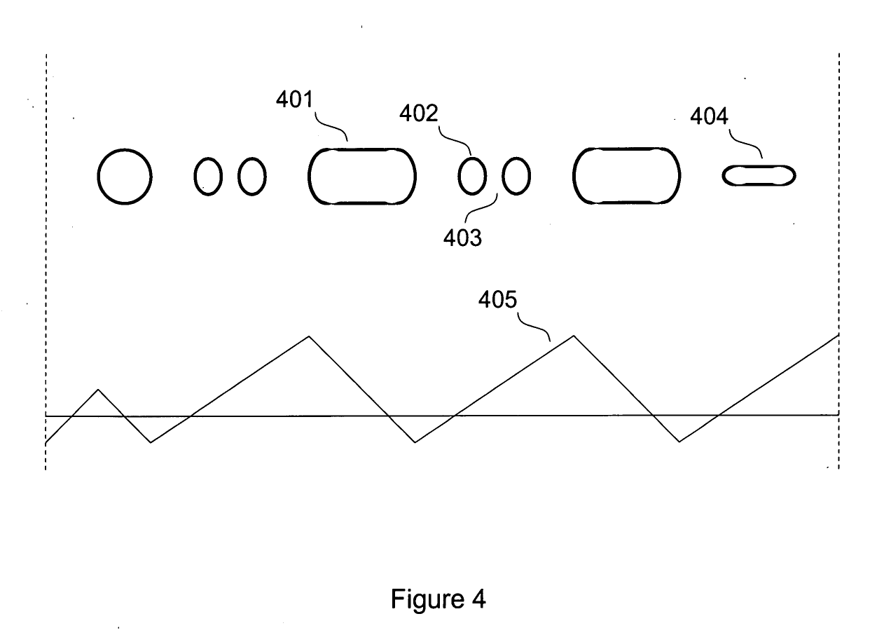

FIG. 4 illustrates a variable geometry land pit sequence. It includes normal pit structures such as structure 401 and land regions with small dimension pits such as 402 separated by small dimension land regions 403. An alternative variable geometry structure is shown by the narrow long pit 404. The resulting accumulated DSV signal 405 does not rise in average value, despite the increasing average value of the bit stream's mathematical DSV.

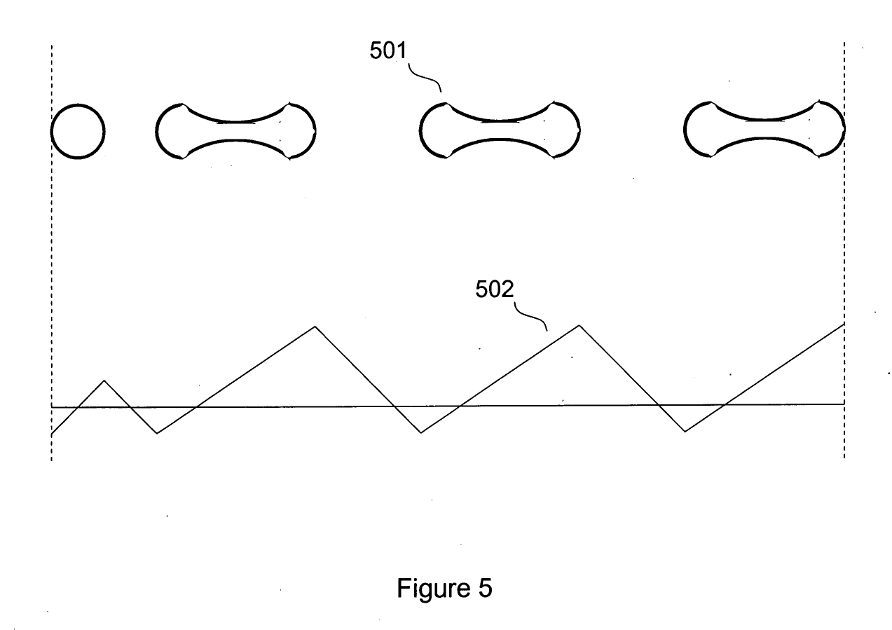

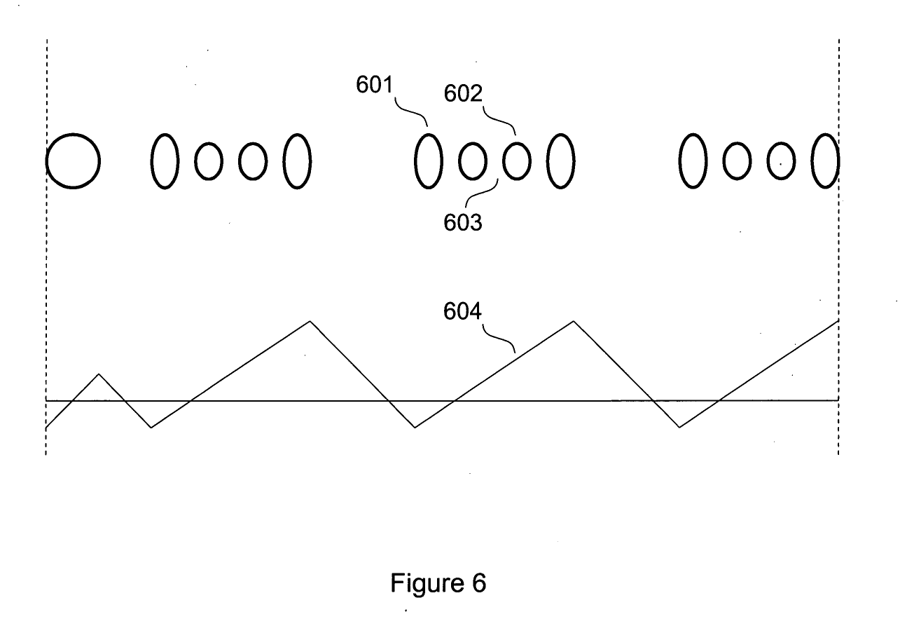

FIG. 5 illustrates yet another variable geometry land pit sequence with normal land and pits with reduced widths 501 away from their lead and lag transitions. The normal lead and lag transition regions maintains normal signal characteristics at the critical transition points. Again the DSV signal 502 is non-problematic. FIG. 6 is a further illustration of a variable geometry land pit sequence with normal land regions and pit regions consisting of multiple pits 601, 602 with different geometries, separated by small dimension land 603. The DSV signal 604 is again non-problematic.

These various variable pit geometries can be further modified to pre-compensate for inter-symbol interference or the characteristics of the read channel (or detection schemes such as PRML). For example, the horizontal or vertical dimensions (major axes) of pits such as pit 402 could be adjusted to reduce inter-symbol interference along the data track. The vertical symmetry of pits could be adjusted (for example by locating them slightly off-track) to reduce inter-symbol interference between tracks. By various combinations of symmetrical and asymmetrical geometrical adjustments, variable pit geometries are selected to compensate for inter-symbol interference. Reduced inter-symbol interference allows increased storage capacity by allowing sequences with reduced channel bit dimensions (or physically closer channel bit spacing or track spacing).

Similarly, variable pit geometries are selected to enhance PRML detection of sequences with reduced channel bit dimensions. This also allows increased storage capacity by again allowing physically closer channel bit spacing or track spacing, while still allowing reliable recovery of data by the read channel (or PRML detection scheme)

Removing or reducing the requirement of channel code choices to control DSV enables using a more efficient channel code which also enables increased storage capacity. For example, a code with rate 8 to 15 is enabled for a format for a red laser DVD generation. This provides an additional storage capacity over and 8 to 16 code of approximately 6%. A specific example of such a code is described in U.S. Pat. No. 6,002,718. It includes an RLL code of rate 8 to 15 with similar characteristics to the 8 to 16 EFMplus code employed in current DVD formats.

The code allows sequences of 12 zeros in a row, which is les than the 13 zeros in a row of the current DVD sync sequences. It also has the same degree of byte error propagation as the current DVD format, however the decoding process is simpler and only requires the single immediately following bit of a following 15 bit sequence to decode a non-block decodable 15 bit sequence. The 8 to 15 code also has some usable and effective DSV control capability. Therefore using variable geometry pits to address, at least in part, the DSV control requirement allows using a modulation code that enables higher storage capacity.

For storage applications, such as video or audio (including movies and music) where a continuous data stream is required, error correction codes that require time consuming iterative processing are effectively unusable and therefore represent wasted capacity, since the interruption caused by the iterative processing is at least as objectionable as errors (which have the opportunity of being concealed).

However, current storage systems, such as DVD, do not distinguish between conventional data blocks for which full error correction is critical and transitional data blocks for which a continuous data stream is more desirable than absence of errors. For purposes of this application transitional data or reduced data blocks shall refer to data blocks for which a continuous data stream is more desirable than total absence of errors.

Tagging the addresses of transitional data blocks and conventional blocks enables recording transitional blocks with reduced error correction codewords and thereby making additional storage capacity available.

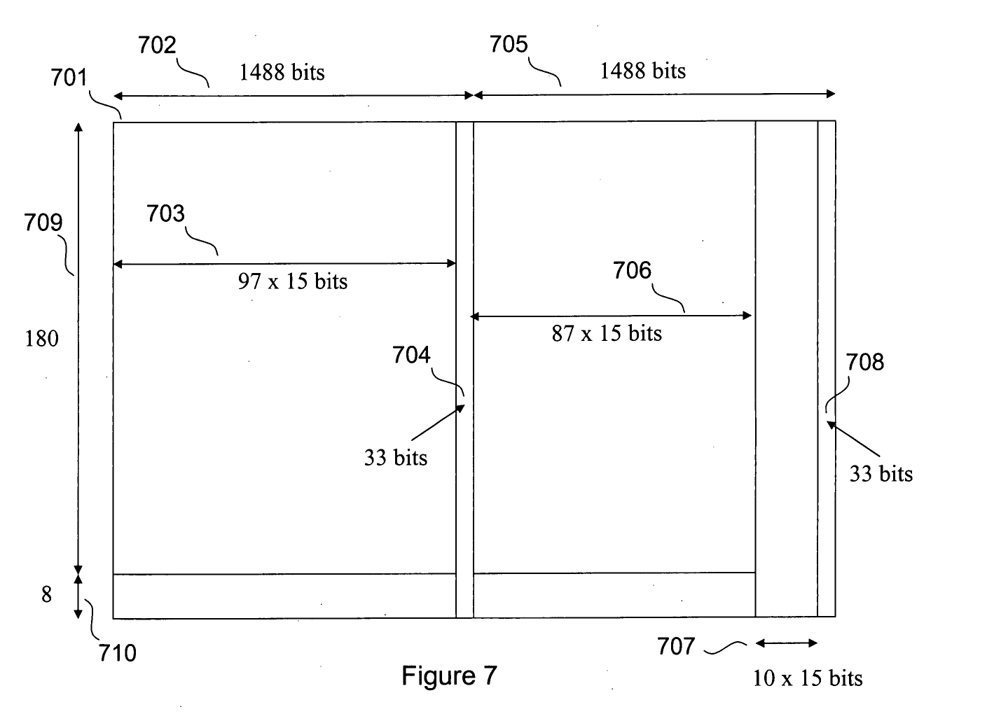

An example of such a transitional data block suitable for the DVD environment is illustrated in FIG. 7. The basic unit is a line 701 consisting of two units of 1488 bits. The first unit (illustrated by 702) is comprised of 97 fifteen bit data sequences (illustrated by 703) and a 33 bit sync sequence (illustrated by 704). (These units are similar to the “sync frames” of the standard DVD format. The second unit (illustrated by 705) also consists of 1488 bits, comprised of 87 fifteen bit data sequences (illustrated by 706), 10 fifteen bit first level ECC sequence (illustrated by 707) s and a 33 bit sync sequence (illustrated by 708).

The reduced block consists 188 lines of which 180 (illustrated by 709) contain data and the remaining 8 lines (illustrated by 710) are ECC lines and contain 184 fifteen bit ECC second level sequences, their 10 fifteen bit first level ECC sequences and two 33 bit sync sequences.

Reducing the number of second level ECC lines reduces the magnitude of burst errors that can be corrected, however, by interleaving two such reduced data blocks (on a line by line basis) allows correcting similar magnitude of burst errors. The physical length of a bit in the standard DVD format is consistent with interleaving two blocks because they would span less than one revolution at the inner diameter of the user data region. The interleaved pair of reduced blocks are thus short enough to not overlap (which could allow double exposure to the same errors).

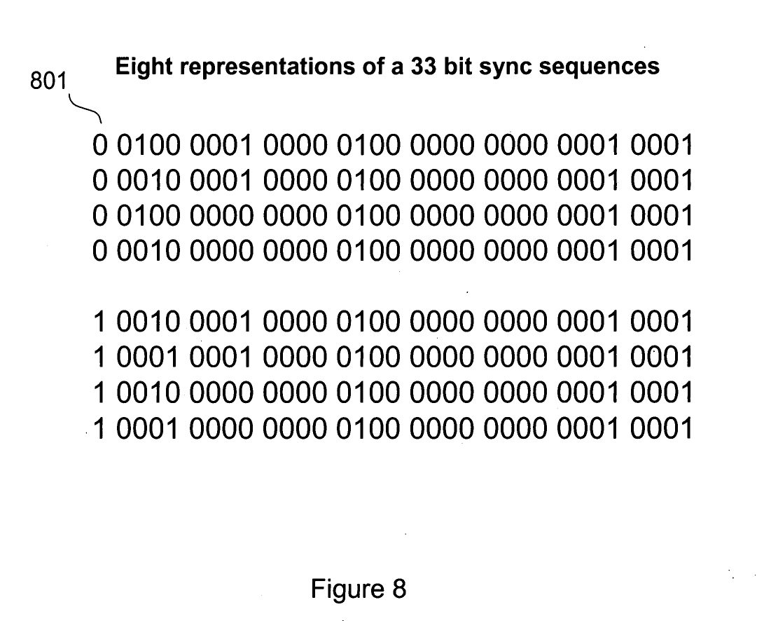

An example of a set of 33 bit sync sequences 801 is illustrated in FIG. 8. In the preferred embodiment each sync sequences has 8 possible representations. All 8 contain the unique 18 bit synchronization sequence “00 0100 0000 0000 0001 0001” the remaining 15 bit sequences have 8 different-variations. Of these 4 begin with “0” and 4 with “1”, and this first bit is used to correctly decode the previous data byte, if required. Each set of 4 has two subsets of 2. One subset of 2 has even parity (number of ones) and the other subset of 2 has odd parity, allowing for DSV control. One sequence of each subset of 2 represents a sub-channel data bit 0 and the other represents a sub-channel data bit 1, providing a sub-channel bit rate of one bit per sync sequence.

Multiple sets of 33 bit sequences are available and may be used to identify specific sync sequences within the data block. Many variations of these sync sequences are possible and if sufficient DC control is available from the variable geometry approach, each sync set can be reduced to 4, furthermore if a lower sub-channel rate is sufficient, then some sync sequences need only two 2 representations. Thus there is great flexibility in sync sequence design.

Encoding 1 bit per sync sequence provide up to 376 bits, or 47 eight bit bytes per block. This can readily be configured to include block start identification data, block address data, payload data, and error correction data.

The payload data is suitable for being used for copy protection purposes. For example it could include encryption, decryption or descrambling data. Such data could include encryption, decryption or descrambling keys or public or private keys. An advantage of storing such data in this sub-channel data stream is that it is only decoded at a very deep level in a drive and is out of band from the normal user data. Therefore it is not typically transferred with a copy of user data, therefore it is volatile data.

A valuable use of this volatile data carrying capability is to use it in conjunction with a non volatile watermark in the decoded data. This can be used as the basis for a copy protection scheme wherein the drive can request cryptographically related data from a compliant decoder (such as a video decoder) and a compliant decoder can request cryptographically related data from the drive, which is only available if the drive is playing a legitimate disc.

The cryptographically related data can be exchanged between decoder and drive by means of conventional cryptographic techniques, such as key exchange protocols. A failure of this protocol would result in data on the disc being withheld, thus comprising a barrier against playing unauthorized copies.

A significant advantage of this sub-channel over previously proposed sub-channels is that the sub-channel is available at a determined rate (not dependent on statistically occurrences). This enables a rapid dynamic, real time, challenge response protocol to provide copy protection measures that are difficult to counter in a pre-determined circumventing utility program.

The variable geometry pits that enable this higher capacity disc can be generated in a typical mastering system, such as, a laser beam recorder mastering system or an electronic beam recorder mastering by varying the power and the tracking (or steering) of the one or more beams used in the mastering process. Control over the power and tracking of the beam or beams can be used to define the variable geometry pit sequence on photo-resist material. The master disc is then generated typically by an etching process to generate the variable geometry land pit sequence.

ROM discs fabricated using this master, with high quality, high resolution replication devices are non-problematic and are generally playable in consumer disc players (or readers). Discs with reduced data blocks will require drives with modified electronic processing. Similarly drives that process the synch sub channel or use a more efficient modulation code, or require PRML detection would also require modified electronic processing. Such drives with modified electronic processing would be suitable for higher performance proprietary drives for specific applications (such as games) and could readily include the ability to play standard discs. New and emerging formats could include versions of all of these techniques.

Typically consumer recorders, such as CD−R, CD−RW, DVD−R, DVD−RW, DVD+RW, etc., however, will not be able to reproduce variable geometry marks. Similarly, low quality, low resolution duplicators using stripped ROM discs as unauthorized masters will not have the capability of generating variable geometry marks or pits and will therefore yield copied discs that are problematic on playback, and in any event do not have the increased storage capability.

An example of a possible implementation of this system, would be storing HDTV movies on a two layer DVD type disc with the additional storage capacity and copy protection capability enabled by variable geometry pits. This, coupled with advances in video compression technology would enable releasing HDTV movies on conventional DVD discs with higher quality and increased protection against unauthorized copying.

It is understood that the above description is intended to be illustrative and not restrictive. Many of the features have functional equivalents that are intended to be included in the invention as being taught. For example, many variations and combinations of the variable geometry sizes of pits are possible and this approach is applicable to various generations of technology, including the present CD and DVD systems, emerging Blu Ray and AOD versions and future as yet undefined versions.

Variable geometry pits can include more elaborate and asymmetric geometries. Accurate and predetermined control of DSV by means of variable geometry enables standard optical heads to read increased bit density sequences (shorter bit lengths). Variable geometry pits can also be used to facilitate and enhance more elaborate detection schemes, including but not limited to the many advanced variations of Partial Response Maximum Likelihood (PRML). This enables a reduction of channel bit dimensions which enables further increase in storage capacity.

Other higher efficiency modulation code (than the 8 to 15 one referenced) can be used as can other variations of the sync sequences, including ones not 33 bits long. While current consumer writers do not have the capability of writing variable geometry space mark sequences, future drives could be developed with this capability and could therefore avail of the increased storage capacity techniques described above. Therefore, for purposes of this application a variable geometry land pit sequence includes a variable geometry space mark sequence and mastering includes writing to recordable consumer discs.

The scope of this invention should therefore not be determined with reference to the above description, but instead should be determined with reference to the appended claims and drawings, along with the full scope of equivalents to which such claims and drawings are entitled.

1. A method of increasing the storage capacity of discs, the method comprising:
encoding a sequence of symbols into a channel bit sequence which may include problematic digital sum variance;
monitoring the digital sum variance of the channel bit sequence;
generating a non-problematic variable geometry land pit sequence; and
recording the non-problematic variable geometry land pit sequence.

2. A method of increasing the storage capacity of discs, the method comprising:
encoding a sequence of symbols into a channel bit sequence;
monitoring inter-symbol interference of the channel bit sequence;
generating a non-problematic variable geometry land pit sequence with reduced channel bit dimensions; and
recording a non-problematic variable geometry land pit sequence.

3. The method of claim 2, wherein the variable pit geometries are selected to compensate for inter-symbol interference.

4. The method of claim 2, wherein the variable pit geometries are selected to enhance PRML detection of sequences with reduced channel bit dimensions.

5. A method of increasing the storage capacity of discs, the method comprising:
tagging at least one sequence of symbols as requiring a continuous data stream;
generating a reduced set of error correction codewords for said sequence of symbols;
combining the sequence of symbols and the reduced set of error correction codewords;
encoding the combined sequence of symbols into a channel bit sequence; and
recording said channel bit sequence.

6. A method of inhibiting copying of digital information, the method comprising:
generating a first sequence of bits;
selecting synchronizing bit sequences based on the first sequence of bits;
combining the selected synchronizing bit sequences with a second sequence of bits; and
recording the combined sequence of bits on a disc.

7. The method of claim 6, wherein the first sequence of bits is decryption related data.

8. The method of claim 6, wherein the first sequence of bits is related to data contained in a watermark.

9. The method of claim 6, wherein the first sequence of bits includes bits related to error correction data.

10. The method of claim 6, wherein a restricted set of data sectors are enabled for selecting synchronizing bit sequences.

11. An apparatus for increasing the storage capacity of discs comprising:
means for encoding a sequence of symbols into a channel bit sequence which may include problematic digital sum variance;
means for monitoring the digital sum variance of the channel bit sequence;
means for generating a non-problematic variable geometry land pit sequence; and
means for recording the non-problematic variable geometry land pit sequence.

12. An apparatus for increasing the storage capacity of discs comprising:
means for encoding a sequence of symbols into a channel bit sequence;
means for monitoring inter-symbol interference of the channel bit sequence;
means for generating a non-problematic variable geometry land pit sequence with reduced channel bit dimensions; and
means for recording a non-problematic variable geometry land pit sequence.

13. The apparatus of claim 12, wherein the variable pit geometries are selected to compensate for inter-symbol interference.

14. The apparatus of claim 12, wherein the variable pit geometries are selected to enhance PRML detection of sequences with reduced channel bit dimensions.

15. An apparatus for increasing the storage capacity of discs comprising:
means for tagging at least one sequence of symbols as requiring a continuous data stream;
means for generating a reduced set of error correction codewords for said sequence of symbols;
means for combining the sequence of symbols and the reduced set of error correction codewords;
means for encoding the combined sequence of symbols into a channel bit sequence; and
means for recording said channel bit sequence.

16. An apparatus for inhibiting copying of digital information comprising:
means for generating a first sequence of bits;
means for selecting synchronizing bit sequences based on the first sequence of bits;
means for combining the selected synchronizing bit sequences with a second sequence of bits; and
means for recording the combined sequence of bits on a disc.

17. The apparatus of claim 16, wherein the first sequence of bits is decryption related data.

18. The apparatus of claim 16, wherein the first sequence of bits is related to data contained in a watermark.

19. The apparatus of claim 16, wherein the first sequence of bits includes bits related to error correction data.

20. The apparatus of claim 16, wherein a restricted set of data sectors are enabled for selecting synchronizing bit sequences.

21. A system for increasing the storage capacity of discs comprising:
encoding a sequence of symbols into a channel bit sequence which may include problematic digital sum variance;
monitoring the digital sum variance of the channel bit sequence;
generating a non-problematic variable geometry land pit sequence; and
recording the non-problematic variable geometry land pit sequence.

22. A system for increasing the storage capacity of discs comprising:
encoding a sequence of symbols into a channel bit sequence;
monitoring inter-symbol interference of the channel bit sequence;
generating a non-problematic variable geometry land pit sequence with reduced channel bit dimensions; and
recording a non-problematic variable geometry land pit sequence.

23. A system for inhibiting copying of digital information, the method comprising:
generating a first sequence of bits;
selecting synchronizing bit sequences based on the first sequence of bits;
combining the selected synchronizing bit sequences with a second sequence of bits; and
recording the combined sequence of bits on a disc.

24. A computer readable medium containing an executable program for inhibiting copying of digital information, where the program performs the steps of:
generating a first sequence of bits;
selecting synchronizing bit sequences based on the first sequence of bits;
combining the selected synchronizing bit sequences with a second sequence of bits; and
recording the combined sequence of bits on a disc.

25. The computer readable medium as in claim 24, wherein the first sequence of bits is decryption related data.

26. The computer readable medium as in claim 24, wherein the first sequence of bits is related to data contained in a watermark.

27. The computer readable medium as in claim 24, wherein the first sequence of bits includes bits related to error correction data.

28. The computer readable medium as in claim 24, wherein a restricted set of data sectors are enabled for selecting synchronizing bit sequences.
